(19) United States
(12) Patent Application Publication
(10) Pub. No.: US 2023/0010230 A1
(43) Pub. Date: Jan. 12, 2023

(54) AUXILIARY MIDDLE FRAME PREDICTION LOSS FOR ROBUST VIDEO ACTION SEGMENTATION

(71) Applicant: Intel Corporation, Santa Clara, CA (US)

(72) Inventors: Anthony Rhodes, Portland, OR (US); Sovan Biswas, Bonn (DE); Giuseppe Raffa, Portland, OR (US)

(21) Appl. No.: 17/932,339

(22) Filed: Sep. 15, 2022

(51) Int. Cl. G06V 10/776; G06V 10/82; G06V 20/40; G06V 20/70; G06V 10/774

(52) U.S. Cl. CPC G06V 10/776; G06V 10/82; G06V 20/49; G06V 20/70; G06V 20/46; G06V 10/774

(57) ABSTRACT

Systems, apparatuses, and methods include technology that identifies, with a neural network, that a predetermined amount of a first action is completed at a first portion of a plurality of portions. A subset of the plurality of portions collectively represents the first action. The technology generates a first loss based on the predetermined amount of the first action being identified as being completed at the first portion. The technology updates the neural network based on the first loss.

### TECHNICAL FIELD

Embodiments generally relate to an input data (e.g., video, audio, etc.) segmentation model. More particularly, embodiments relate to enhancing a performance of an action segmentation and action labelling neural network mode through an action completion auxiliary training process on the neural network model.

### BACKGROUND

Some real-world automation domains require frame-level action segmentation across challenging, long duration data (e.g., videos and audio recordings). In particular, application domains that rely on fine-grain action inference in long-tail data distributions and/or include action classes that are difficult to differentiate may pose significant challenges (e.g., over-segmentation and/or misclassification). For example, it may be difficult to identify segments within data streams due to noisy transitions between actions.

### BRIEF DESCRIPTION OF THE DRAWINGS

The various advantages of the embodiments will become apparent to one skilled in the art by reading the following specification and appended claims, and by referencing the following drawings, in which:

FIG. 1 is an example of an auxiliary loss training architecture according to an embodiment;

FIG. 2 is a flowchart of an example of a method of executing auxiliary training to identify completion points according to an embodiment;

FIG. 3 is an example of a ground truth generation architecture according to an embodiment;

FIG. 4 is an example of a middle frame prediction loss function architecture according to an embodiment;

FIG. 5 is an example of a confidence/model prediction calibration graph according to an embodiment;

FIG. 6 is a diagram of an example of an efficiency-enhanced computing system according to an embodiment;

FIG. 7 is an illustration of an example of a semiconductor apparatus according to an embodiment;

FIG. 8 is a block diagram of an example of a processor according to an embodiment; and

FIG. 9 is a block diagram of an example of a multi-processor based computing system according to an embodiment.

### DESCRIPTION OF EMBODIMENTS

Input data (e.g., manufacturing applications where the “idle” class is predominant and different action classes frequently share strong visual similarities) may be difficult to parse and classify. Such input data may be live data streams where actions are being executed in real-time. Artificial intelligence (AI) inference of such input data to divide the live data stream into segments and applying action classes to the segments (e.g., classifying) may pose challenges. Embodiments herein enhance the robustness of fine-grain action inference through an introduction of an auxiliary loss function during training. The auxiliary loss function may be used in combination with any classification-based loss function (e.g., cross-entropy loss) during training.

In detail, for each unique action segmentation, a Middle Frame Prediction Loss (MFPL) function component elicits an auxiliary label prediction (e.g., a label prediction that is implicitly correlated with the primary task of segmentation and classification) for action frame “completion points” (e.g., a midpoint, a portion at which a predetermined amount of the action is completed, etc.). Such action frame completion points may correspond to a middle frame index (e.g., 50% of action is completed) of a contiguous individual action sequence. For example, if an “action a” comprises a sequence of 100 consecutive frames, then the model may predict frame index 50 as the “middle frame.” The middle frame may however be different from half the total number of frames for an action. For example, in some cases parts of the task may be executed more slowly due to constraints (e.g., waiting for parts, resting between arduous portions of the action, power constraints in automated environments, pauses to avoid interference from other machinery, etc.), or be executed more quickly. Thus, the midpoint of an action (e.g., screwing in a screw) may not always be at exactly at the middle (e.g., fifth frame) of a segment (e.g., ten frames long).

By learning the midpoint of various actions, embodiments implicitly learn the expected duration of such actions. Thus, despite noisy transition points between actions, embodiments may still nonetheless identify segments of actions with increased accuracy, robustness, reliability and efficiency than other conventional systems. Furthermore, different actions may be more easily discerned and separated from each other. That is, since the duration of actions are accurately identified, action transition points may be more easily disambiguated and identified despite noisy transitions. In contrast, conventional examples may only be trained to identify transition points between actions and are thus less efficient, less robust, less accurate and less reliable. It is worthwhile to note that the duration of different actions may be variable, ranging from seconds to hours.

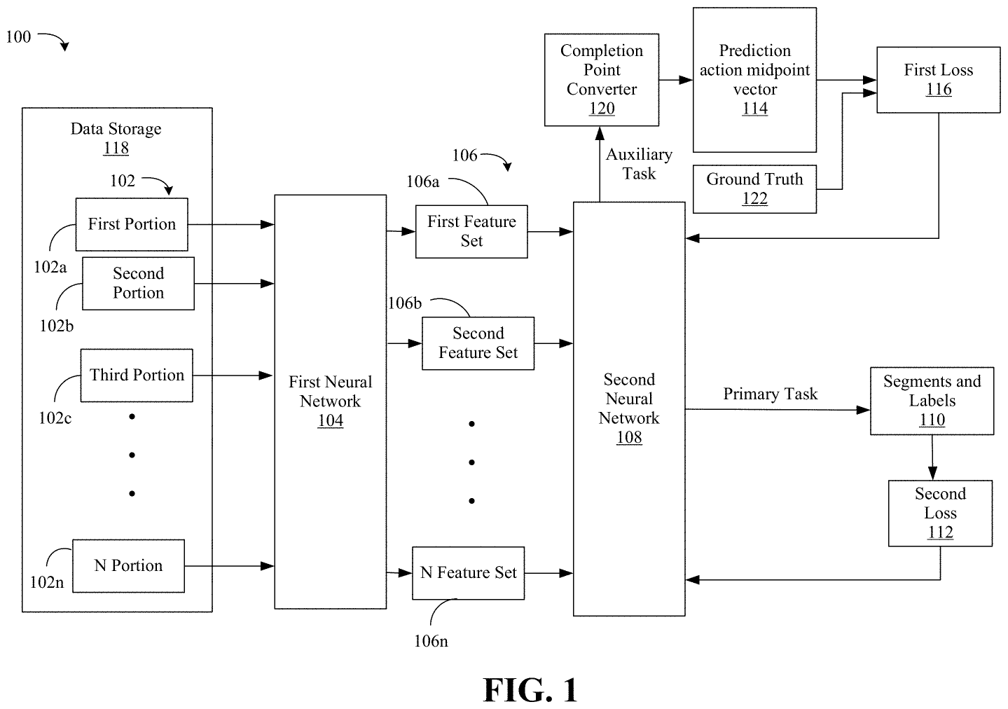

Turning now to FIG. 1, an auxiliary loss training architecture 100 is illustrated. The auxiliary loss training architecture 100 may be an action segmentation model that includes an auxiliary task (e.g., MFPL) that prompts a second neural network 108 to predict whether a completion point (e.g., midpoint) of an action occurs in each frame of each contiguous action segment in input data 102 (e.g., a video or audio recording). The completion point may correspond to an amount of the total/all the action. The input data 102 may include sensors data, audio data, hand tracking data, language data, video stream data, object localization data, semantic segmentation data, etc. In some embodiments, the input data 102 is a video feed (e.g., a live video feed or a previously recorded feed). The input data 102 may represent a temporally evolving process (e.g., hand movement in a manufacturing environment) that comprises several distinct actions.

The input data 102 may include multiple temporally evolving actions, and the second neural network 108 may be expected to determine whether each frame of the input data 102 corresponds to a completion point where an amount of a respective action is completed. It will be understood that the input data 102 may include only a single action in some embodiments.

The input data 102 includes first-N portions 102a-102n. The first-N portions 102a-102n may each correspond to a different portion of the actions. In some examples, each of the first-N portions 102a-102n may be a video frame. In some examples, each of the first-N portions 102a-102n may be an audio frame. In some examples, each of the first-N portions 102a-102n may be a video frame with corresponding audio (e.g., a multi-modal frame). The input data 102 is stored in a data storage 118.

A first neural network 104 analyzes the input data 102 to extract and/or identify features 106. The features 106 include first feature set-N features set 106a-106n (e.g., frame-wise feature vectors). The first neural network 104 may be a convolutional neural network (CNN) in some examples. The first feature set-N features set 106a-106n correspond to the first-N portions 102a-102n. For example, the first feature set 106a may correspond to the first portion 102a, the second feature set 106b may correspond to the second portion 102b, the N feature set 106n may correspond to the N portion 102n and so forth. As noted above, each of the first-N portions 102a-102n may be a different frame of an action(s). In some embodiments, the first neural network 104 may be a pre-trained Slow-Fast 50 3 Dimensional (3D) CNN architecture that extracts global frame-wise features from the input data 102 (e.g., raw video)

A second neural network 108 may be a temporal convolutional network (TCN). A TCN may be an architecture which employs casual convolutions and dilations (e.g., 1D fully-convolutional network and causal convolutions) to be adaptive for sequential data with its temporality and large receptive fields. TCNs may be a class of time-series models that capture long range patterns using a hierarchy of temporal convolutional filters. A decoder TCN may only uses a hierarchy of temporal convolutions, pooling, and upsampling. A dilated TCN uses dilated convolutions instead of pooling and upsampling and adds skip connections between layers. A TCN may efficiently analyze long duration videos and/or recordings and is thus applied to the embodiments described herein. The second neural network 108 may have a primary task of segmentation and classification. For example, the second neural network 108 may be an action segmentation architecture that aims to segment a temporally untrimmed video by time. Further, the second neural network 108 may classify and label each segment with one of pre-defined action labels (e.g., screwing, unscrewing, moving object, etc.). The results of the action segmentation may be used as input to various applications, such as video-to-text, action localization, home security, healthcare, robot automation, driverless technology, automated actions, etc. to form future action decisions. To do so, the second neural network 108 may not only analyze a current feature set (e.g., corresponding to a current video frame) of the first-N feature sets 106a-106n, but may also analyze past feature sets (e.g., corresponding to past video frames relative to the current video frame) of the first-N feature sets 106a-106n, temporally adjacent feature sets of the first-N feature sets 106a-106n and future feature sets (e.g., corresponding to future video frames sets relative to the current video frame) of the first-N feature sets 106a-106n.

In order to avoid over-segmentation and more accurately segment actions from raw data, embodiments employ an auxiliary training (also referred to as learning) process. Auxiliary learning may be a method to enhance the ability of the second neural network 108 to execute a primary task (e.g., segmentation, classification and labelling of the segments) by training on an additional auxiliary task (e.g., identify a completion point of an action such as a midpoint) alongside this primary task. The concurrent training of multiple tasks enables a sharing of features across tasks and results in additional relevant features being available, which otherwise may not have been learned from training only on the primary task. The broader support of these features, across new interpretations of input data, then allows for better generalization, application and accuracy of the second neural network 108 executing the primary task. Auxiliary learning may be similar to multi-task learning, except that only the performance of the primary task is of importance in auxiliary learning, and the auxiliary task(s) are included purely to assist the primary task. In this example, while auxiliary learning is described where the primary task of the second neural network 108 is segmentation, classification and labelling during inference, it will be understood that some embodiments may include multi-task learning where the second neural network 108 is to both execute the primary task and auxiliary task during inference.

The second neural network 108 generates segments and labels 110 based on the input data 102. For example, the second neural network 108 may determine that a first subset of the first-N portions 102a-102n corresponds to a first action, and a second subset of the first-N portions 102a-102n corresponds to a second action. The second neural network 108 may label each of the first action and the second action with an action class. The action class classifies the action (either the respective first or second action). For example, the first action may be a drilling action class, while the second action may be a screw insertion class. The segments and labels 110 may be the primary task of the second neural network 108.

As the auxiliary task, the second neural network 108 may identify a predetermined completion point (e.g., action is in total 40% completed, 50% completed, 60% completed, etc.) of the first and second actions. For example, the second neural network 108 may determine that a predetermined amount of an action is completed at a specific portion of the portions 102a-102n. For example, as noted above, the first action comprises a first subset of the first-N portions 102a-102n. The first subset may include the first, second and third portion 102a, 102b, 102c (e.g., different frames of a video). The second neural network 108 may identify that the predetermined completion point (e.g., midpoint) of the first action occurs at the second portion 102b. Similarly, the second neural network 108 may identify the predetermined completion point for the second action from the second subset.

The completion point converter 120 may receive an output for the auxiliary task from the second neural network 108. For example, the second neural network 108 may output the completion points (or an output that encompasses the auxiliary task and the primary task) for the first and second actions within the first and second subsets respectively. The completion point converter 120 may extract the completion point from the output of the second neural network 108, and convert the extracted completion point output from the second neural network 108 into a vector format. For example, the completion point converter 120 may be an MFPL module which may be a modular subnetwork that includes a residual net architecture. A residual net network with residual connections may mean that the residual net network contains connections where previous layer representations are directly connected to subsequent network layers, improving information flow efficiency in the network. The completion point converter 120 may excise a portion of an output matrix of the output of the second neural network 108 to retrieve the auxiliary task from the output of the second neural network 108. In doing so, the completion point converter 120 generates a raw vector. The raw vector is processed by several layers of 1D convolutions with residual skip connections (e.g., convolution layers). The completion point converter 120 then processes the raw vector with a sigmoid activation to modify the raw vector into a prediction action midpoint vector 114 (e.g., a first vector in binary format) which indicates the positions of the completion points in respective portions of the first-n portions 102a-102n.

The auxiliary loss training architecture 100 then generates a first loss 116 based on a ground truth 122 (e.g., a second vector) and the prediction action midpoint vector 114. For example, the prediction action midpoint vector 114 may be compared to the ground truth 122 to generate the first loss 116. The second neural network 108 may be updated (e.g., weights, activation functions, biases, etc.) based on the first loss 116.

The second neural network 108 may generate segments and labels 110 as discussed above. The auxiliary loss training architecture 100 then generates a second loss 112 based on the segments and labels 110. In some examples, the second loss 112 may be generated based on a comparison of the segmentation and labels 110 to a ground truth. The second neural network 108 is then updated (e.g., weights, activation functions, biases, etc.) based on the second loss 112. In some embodiments, the second neural network 108 may be updated based on a combined loss function that combines the first and second losses. The training process may execute over a number of iterations until the second neural network 108 is deemed to be accurate (e.g., an accuracy metric of a number of correct answers compared to ground truths is above a threshold).

It is worthwhile to note that while a completion point is indicated above, more than one completion may be identified per action. Furthermore, the completion point may be a range of values (e.g., 45%-55%) to include multiple frames in some examples. Thus the auxiliary loss training architecture 100 may be a robust segmentation and labelling system that is able to identify segments efficiently and accurately from input data 102, and label the segments accordingly. Moreover, the auxiliary loss training architecture 100 may have less overhead than other conventional systems due to the labor division between the first neural network 104 (a larger scale CNN) and the second neural network 108 (a lightweight TCN).

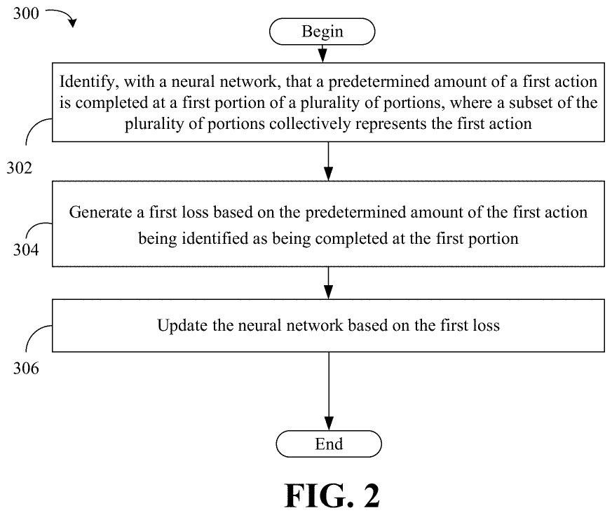

FIG. 2 shows a method 300 of executing auxiliary training to identify completion points according to embodiments herein. The method 300 may generally be implemented with the embodiments described herein, for example, an auxiliary loss training architecture 100 (FIG. 1) already discussed. More particularly, the method 300 may be implemented in one or more modules as a set of logic instructions stored in a machine-or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic include suitably configured programmable logic arrays (PLAs), field programmable gate arrays (FPGAs), complex programmable logic devices (CPLDs), and general purpose microprocessors. Examples of fixed-functionality logic include suitably configured application specific integrated circuits (ASICs), general purpose microprocessor or combinational logic circuits, and sequential logic circuits or any combination thereof. The configurable or fixed-functionality logic can be implemented with complementary metal oxide semiconductor (CMOS) logic circuits, transistor-transistor logic (TTL) logic circuits, or other circuits.

For example, computer program code to carry out operations shown in the method 300 may be written in any combination of one or more programming languages, including an object-oriented programming language such as JAVA, SMALLTALK, C++or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 302 identifies, with a neural network, that a predetermined amount of a first action is completed at a first portion of a plurality of portions, where a subset of the plurality of portions collectively represents the first action. Illustrated processing block 304 generates a first loss based on the predetermined amount of the first action being identified as being completed at the first portion. Illustrated processing block 306 updates the neural network based on the first loss.

In some embodiments, the method 300 generates a first vector based on the subset of the plurality of portions and the predetermined amount of the first action being identified as being completed at the first portion, and identifies a second vector that is a ground truth. The generating the first loss comprises comparing the first vector to the second vector. The method 300 further comprises processing, with the neural network, the plurality of portions to generate an output, where the generation of the first vector includes executing, with a plurality of convolution layers, a plurality of convolutions on the output. A plurality of residual connections connects the plurality of convolution layers.

In some embodiments, the method 300 includes processing, with the neural network, the plurality of portions of data to identify segments that correspond to a plurality of actions and label the segments with action labels. The plurality of actions includes the first action. The method 300 further comprises generating a second loss based on the segments and the action labels, and updating the neural network based on the second loss. In some embodiments, the method 300 includes generating, with a convolutional neural network, features of the plurality of portions. The plurality of portions is one or more of video data or audio data and the neural network is a temporal convolutional network. The identifying that the predetermined amount of the first action is completed at the first portion comprises processing the features with the temporal convolutional network, wherein the predetermined amount corresponds to a midpoint of the first action.

The method 300 may result in a more stable measurement of the extent and time of action segments during inference. The method 300 further captures a signal (e.g., action midpoints) that is far less noisy than conventional attempts to explicitly infer action transition points without auxiliary training. The method 300 further additionally encourages the implicit learning of the expected duration of actions which can be elucidating for post hoc analysis and, moreover, provide utility as a regularization tool for applications that consist of standardized and systematic action types (e.g., manufacturing, education visual-based testing, etc.). The method 300 further includes automatic keyframe extraction (e.g., identify the action keyframe as the prediction midpoint frame) for downstream human-in-the-loop validation processes. The method 300 further yields better confidence/model prediction calibration properties.

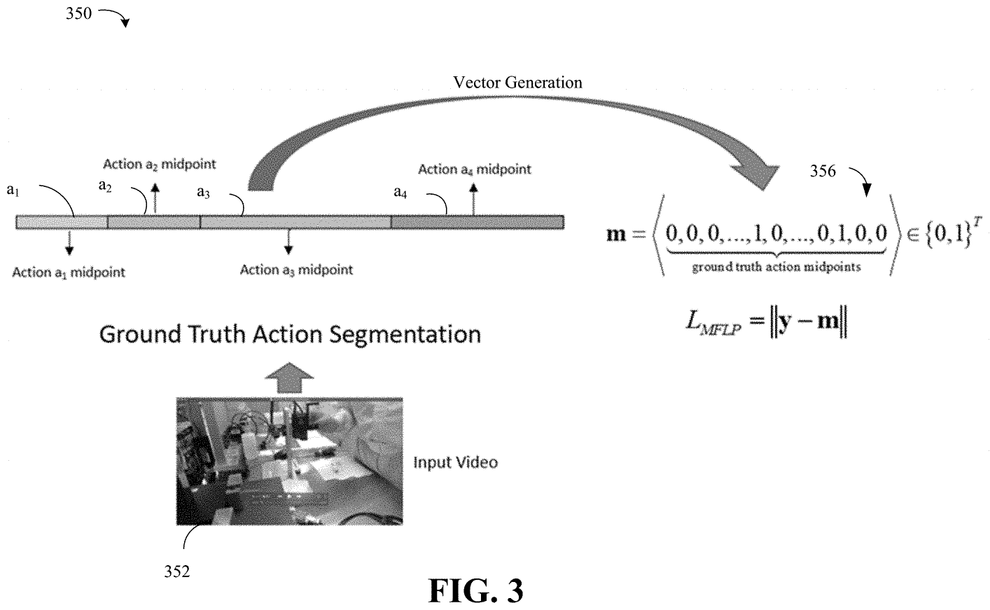

FIG. 3 illustrates a ground truth generation architecture 350 (e.g., a computing architecture or human user). The ground truth generation architecture 350 may generally be implemented with the embodiments described herein, for example, an auxiliary loss training architecture 100 (FIG. 1) and/or method 300 (FIG. 2) already discussed. For example, the ground truth generation architecture 350 may readily generate the ground truth 122. An input video 352 (e.g., input data) is segmented into different actions a₁, a₂, a₃, a₄. The different action a₁, a₂, a₃, a₄ have different midpoints as indicated. The midpoints are identified by, for example, a user. A ground truth vector m is a ground truth that is generated based on the ground truths and the actions frames. For example, each of the different actions a₁, a₂, a₃, a₄ comprises different frames. Vector generation may include labelling each of the frames as being a midpoint of a respective actions a₁, a₂, a₃, a₄ (i.e., 1) or not a midpoint (i.e., 0). Thus, each of the different actions a₁, a₂, a₃, a₄ comprises a plurality of frames, with only one of the frames being labeled as a midpoint. To identify a loss LMFPL, the ground truth vector m is subtracted from a neural network vector y generated by a neural network (e.g., a TCN) that identifies the midpoints. The loss LMFPL corresponds to how correct the neural network vector y is compared to the ground truth vector m.

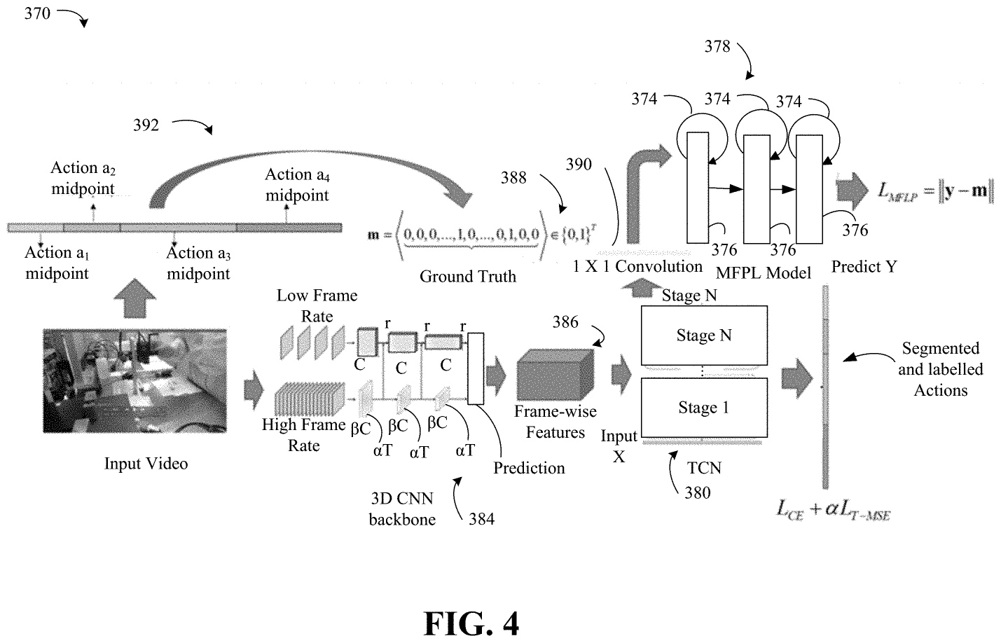

FIG. 4 illustrates a MFPL computing architecture 370. The MFPL computing architecture 370 may generally be implemented with the embodiments described herein, for example, an auxiliary loss training architecture 100 (FIG. 1), method 300 (FIG. 2) and/or ground truth generation architecture 350 (FIG. 3) already discussed. In some examples, a MFPL function may be combined with other sets of classification functions used for video action segmentation. Some examples of classification functions may include an orthodox cross-entropy function. As noted, the MFPL function is an auxiliary function intended to enhance the predictive performance and robustness of existing models by training the TCN 380 (e.g., an action segmentation model) to solve a complementary “action completion point” (e.g., midpoint) task. Thus, the MFPL function may be used in conjunction with other loss functions that are explicitly aligned with action segmentation and labelling (the primary learning task). The TCN 380 may output segmented and labelled actions, which are used to generate losses below.

Some embodiments combine MFPL with two supporting loss functions for the primary task of segmenting and labelling actions. The two supporting loss functions include: (i) a cross-entropy loss function which defines a general classification loss as shown in Equation 1 below:

$${L}_{c e} = \frac{1}{T} {\sum }_{t}^{T} - log ( {y}_{t , c} ) \qquad Equation 1$$

In Equation 1 above, T is the input video length or total number of frames of the video, and y_{t,c} denotes the predicted probability for the ground truth label at time t.

A second loss function includes: (ii) truncated mean-square error (T-MSE) to further improve the quality of class segmentation predictions by reducing the instance of over-segmentation errors through smoothing. The T-MSE is defined in Equation 2 below:

$${L}_{T - MSE} = \frac{1}{T C} {\sum }_{t , c} {△}_{t , c}^{\sim 2} \qquad Equation 2$$

$${△}_{t , c}^{\sim 2} = ( \begin{matrix}{△}_{t , c} \leq τ \\ τ : otherwise\end{matrix} )$$

$${△}_{t , c} = \vert log {y}_{t , c} - log {y}_{t - 1 , c} \vert$$

C is the number of action classes, and y_{t,c} is the probability of an action class c at time/frame t. T is the input video length/frames. y_{t,c} is the probability the model predicts class c from frame t of the input video. The sigma/sum notation captures a double-sum over frames (indexed by “t”) and classes (indexed by “c”).

The computing architecture 370 introduces a lightweight, corresponding MFPL model 378 that includes single residual network blocks 376 (e.g., convolution layers) to extract action midpoint predictions from any generic action segmentation model, which in this example is the TCN 380. The MFPL model 378 is appended to the final layer of the TCN 380 (e.g., an action segmentation TCN). In this example, embodiments render frame-wise features 386 using a large-scale 3D CNN 384, and then pass these frame-wise features 386 to the TCN 380 (e.g., Multi-Stage Temporal Convolutional Network (MSTCN) which is a lightweight neural network). Notably, the TCN 380 is lighter weight (e.g., has lower compute and memory requirements) than the 3D CNN 384 and thus operates with lower memory and compute overhead than the 3D CNN 384 (e.g., a backbone). Thus, embodiments may divide operations between the 3D CNN 384 and the TCN 380 to lower memory and compute overhead. The TCN 380 may include N stages and effectively processes a current frame, prior frames that occurred prior to the current frame to identify an action and/or subsequent frames (e.g., frames that occurred after a current frame) to identify segments and actions associated with the segments.

Embodiments modify the final layer of the TCN 380 by appending a 1×1 convolution operation 390 to the TCN 380 in order to output a matrix of dimension T×(C+1) (as opposed to a T×C matrix), where T denotes the number of input video frames and C represents the number of action classes. Thus, the 1×1 convolution operation 390 receives and recalibrates the output of the TCN 380 (the output may be the same as the segmented and labelled actions). The 1×1 convolution operation 390 receives a vector from the TCN 380 and changes a dimension of the received vector (e.g., changes the vector to 100 dimensions from 1,000 dimensions) to match a number of total frames of the input video and/or of the segmented and labelled actions. Then, embodiments excise the final column of the output matrix of dimension T×(C+1), yielding a vector of dimension T×1. The vector of dimension Tx 1 is passed into the MFPL model 378. The MFPL model 378 comprises several layers of single residual network blocks (e.g., 1D convolutions) 376 (e.g., with a filter of 64) with residual skip connections 374. The residual skip connections 374 enable different layers of the single residual network blocks 376 to communicate with each other and/or themselves. The final layer of the MFPL model 378 includes a sigmoid activation, rendering y∈{(0,1)}−T, to generate a prediction action midpoint vector y. The prediction action midpoint vector y is a vector that indicates the midpoint of the action segments, and may be in a binary format (e.g., a “0” indicates that a corresponding frame is not a midpoint and a “1” indicates that a corresponding frame is a midpoint).

A labeled ground truth 392 is further provided. The labeled ground truth 392 may be generated by a user for example. A ground truth vector 388 may be generated based on the labelled ground truth 386. In the ground truth vector 388, each entry corresponds to whether a corresponding frame is a midpoint or not. If the corresponding frame is a midpoint, then the entry is set to “1.” If the corresponding frame is not a midpoint, the entry is set to “0.”

In embodiments the MFPL function loss (auxiliary function loss) is the 2-norm difference between the ground truth vector 388 (e.g., ground truth binary action midpoint vector) and the predicted action midpoint vector as presented below in Equation 3:

L_{mflp}=∥y−m∥, where m=21 0, 0, 0, . . . , 1, 0, . . . , 0, 1, 0, 0>∈{0, 1}^{t} Equation 3

In Equation 3 above, m represents the ground truth vector 388 for the input video and y denotes the prediction action midpoint vector. The vector m includes ground truth action midpoints denoted as “1.”

Based on the above, a total loss function is a linear combination of Equations (1)-(3), as indicated by Equation 4 below:

L=L_{ce}+60 L_{T-MSE}+βL_{MFLP} Equation 4

In Equation 4, α and β are tunable hyperparameters to increase/decrease the influence.

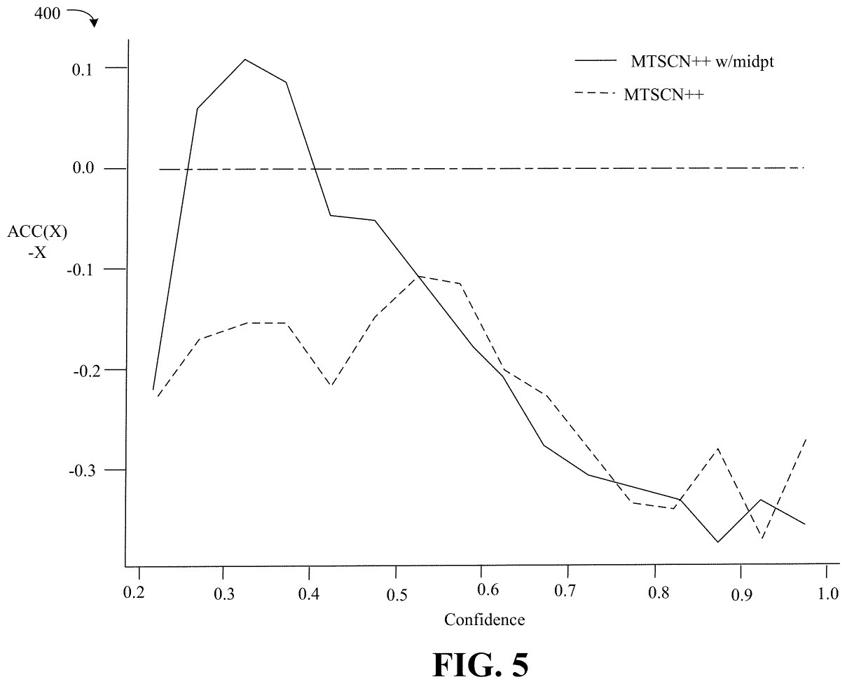

Turning now to FIG. 5, a confidence/model prediction calibration graph 400 of MSTCN (MTSCN++) and MSTCN with MFPL (MTSCN++ w/midpt) is illustrated. Model accuracy is indicated along the y-axis, and model confidence is illustrated along the x-axis. In this example, the confidence/model prediction calibration graph 400 demonstrates the superior calibration property of the TCN using MFPL versus the baseline MTSCN++, particularly in reducing instances of model overconfidence—a common drawback of modern deep learning (DL) models.

To validate the effectiveness of embodiments, below is presented an evaluation on real-world manufacturing data comprising more than 25 video clips (more than 100,000 individual video frames) for the downstream task of fine-grain video action segmentation. The dataset comprises 13 individual class actions. A pre-trained Slow-Fast 50 3D CNN architecture extracted global frame-wise features from raw video; for the final action segmentation inference, embodiments train a MSTCN++ model.

Embodiments generate results for several baseline versions of a workflow, including MSTCN++ (non-causal), meaning that the MSTCN++ model processes video frames in contiguous blocks without being restricted to only “present” and “past” frames. Such a model may be used in post hoc data analysis frameworks. Conversely, MSTCN++(causal), denotes use of the MSTCN++ models where the model may process video frames up to the current frame for action segmentation prediction. Such a model may be used in real-time inference scenarios. In both cases, the experimental results demonstrated significant performance improvements over conventional models when using the MFPL function in conjunction with a lightweight MFPL module. The quantity in parentheses listed under “Frame Accuracy” denotes the best test accuracy achieved by the respective model. Note that in general, strong improvements to precision scores (e.g., “F1@0.10”) are considered to be more practically impactful for deployment purposes due to the frequent highly imbalanced nature of real-world video action segmentation datasets. “F1@ k” denotes a F1 score (average of precision and recall) when the IOU (intersection-over-union) overlap meets a given criterion (e.g., 0.1, 0.25, the corresponding ground truth using a threshold τ etc.). An F1 score is a metric used to measure an effectiveness of a segmentation and classification neural network. A segmental Fl score is applicable to both segmentation and detection tasks and includes the following: (1) F1 score penalizes over-segmentation errors, (2) F1 score avoids penalizing for minor temporal shifts between the predictions and ground truth, which may have been caused by annotator variability, and (3) scores are dependent on the number actions and not on the duration of each action instance. Embodiments compute precision and recall for true positives, false positives, and false negatives summed over all classes and compute F1 according to Equation 5:

$$F 1 = 2 \frac{prec * recall}{prec + recall} \qquad Equation 5$$

Generally, the F1 scores from 0.10-0.50 are greater for embodiments described herein that include MFPL (both causal and non-causal) as opposed to conventional examples.

To further validate the performance enhancement provided by embodiments, results were developed with a technique for leveraging epistemic confidence in multi-modal feature processing, and tested on the same dataset described above. The technique for leveraging epistemic confidence relate to a system that may categorize frames based on a set of variegated data modalities. The variegated data modalities enhance the performance of AI systems by providing a rich substrate of features relevant for downstream tasks (e.g., fine-grain video action recognition, categorization, etc.). Such techniques judiciously fuse multi-modal features based on epistemic confidence (e.g., confidence metric(s)) for downstream tasks. For example, embodiments generate epistemic confidence measures (e.g., epistemic confidence gains) for different multi-modal features with a lightweight neural network (e.g., a neural network, AI network, a temporal network (TN) such as a temporal convolutional network (TCN), etc.). The techniques thus calculate an epistemic confidence gain (ECG) with respect to each feature for each temporal step. The ECG may quantify a degree that the inclusion of a particular feature increases or decreases model confidence at a particular juncture and/or correspond to a degree that the particular feature is relevant for classification of the input data. The techniques calibrate a dynamic multi-modal data fusion process based on the ECG to amplify the influence of informative features, and diminish the influence of and/or exclude less informative features. The combined result of ECG combined with MFPL yielded a very significant performance enhancement in present embodiments over the state-of-the-art MSTCN++ baseline (non-causal) both with and without ECG modeling as measured in F1 metrics described above.

Further, to verify that embodiments herein yield better confidence/model prediction calibration properties (e.g., a vital metric for real-world deployment of data-driven systems). FIG. 5 illustrates the difference between model accuracy and model confidence (shown on the vertical axis) for various confidence levels (horizontal axis). Note that, ideally acc(x)—x should be close to zero (shown as a horizontal dashed line), indicating that the model accuracy is aligned with the model confidence. When acc(x)—x >0, this indicates an “underconfident” model; conversely, when acc(x)—x<0, this denotes an “overconfident” model. FIG. 5 demonstrates the superior calibration property of the TCN using MFPL (MTSCN++) versus the baseline (MTSCN++), particularly in reducing instances of model overconfidence — a common pathology of modern DL models. Equation 6 illustrates an accuracy measurement to judge the confidence of a respective model.

$$Acc ( P ) = \frac{{\sum }_{t} I [ {\hat{y}}_{t} = {y}_{t} ] \cdot I [ {\hat{p}}_{t} ∈ P ]}{{\sum }_{t} I [ {\hat{p}}_{t} ∈ P ]} \qquad Equation 6$$

Thus, embodiments render completion point frame predictions, to include a lightweight module inspired by standard residual network architecture blocks. The MFPL module may be seamlessly appended to the final layer of any conventional video action segmentation model, including temporal convolutional networks (TCNs). MFPL employs a more stable measure of the extent of action segments. Furthermore, MFPL also captures a signal (e.g., completion points such as action midpoints) that are far less noisy than conventional attempts to explicitly infer action transition points.

MFPL additionally encourages the implicit learning of the expected duration of actions which may be elucidating for post hoc analysis and, moreover, provide utility as a regularization tool for applications that consist of standardized and systematic action types (e.g., manufacturing, education visual-based testing, etc.). MFPL may be used as a mechanism for automatic keyframe extraction (i.e., identify the action keyframe as the prediction midpoint frame) for downstream human-in-the-loop validation processes. As embodiments demonstrate, MFPL yields better confidence/model prediction calibration properties. Furthermore, the MFL requires diminutive additional compute and memory overhead.

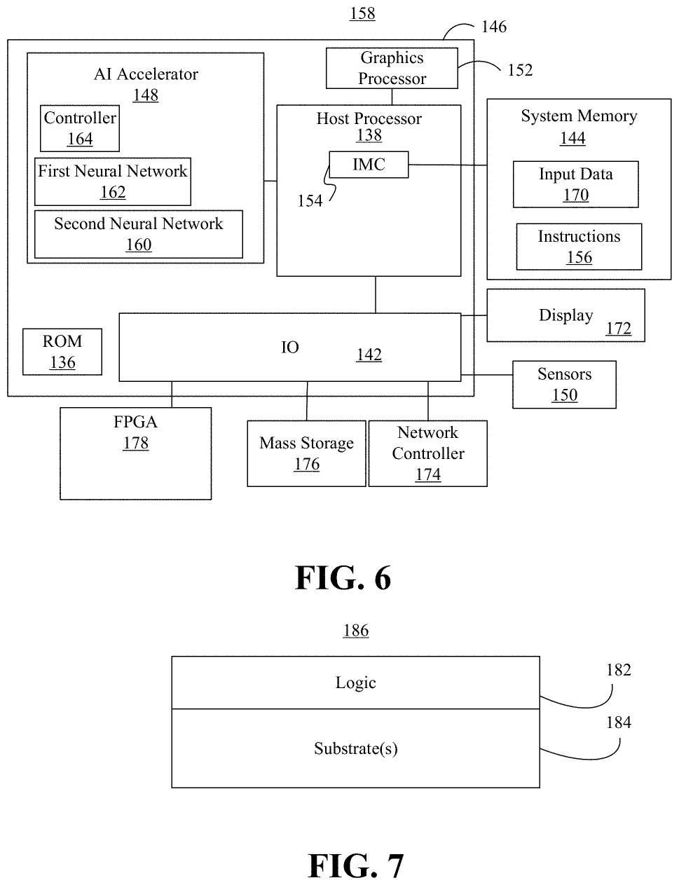

Turning now to FIG. 6, an accuracy and performance-enhanced computing system 158 is shown. The computing system 158 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot, manufacturing robot, autonomous vehicle, industrial robot, etc.), edge device (e.g., mobile phone, desktop, etc.) etc., or any combination thereof. In the illustrated example, the computing system 158 includes a host processor 138 (e.g., CPU) having an integrated memory controller (IMC) 154 that is coupled to a system memory 144.

The illustrated computing system 158 also includes an input output (I0) module 142 implemented together with the host processor 138, the graphics processor 152 (e.g., GPU), ROM 136, and AI accelerator 148 on a semiconductor die 146 as a system on chip (SoC). The illustrated I0 module 142 communicates with, for example, a display 172 (e.g., touch screen, liquid crystal display/LCD, light emitting diode/LED display), a network controller 174 (e.g., wired and/or wireless), FPGA 178 and mass storage 176 (e.g., hard disk drive/HDD, optical disk, solid state drive/SSD, flash memory). The I0 module 142 also communicates with sensors 150 (e.g., video sensors, audio sensors, proximity sensors, heat sensors, etc.). The sensors 150 may provide input data 170 to the AI accelerator 148 to facilitate training according to embodiments as described herein. The SoC 146 may further include processors (not shown) and/or the AI accelerator 148 dedicated to artificial intelligence (AI) and/or neural network (NN) processing. For example, the system SoC 146 may include vision processing units (VPUs,) and/or other AI/NN-specific processors such as the AI accelerator 148, etc. In some embodiments, any aspect of the embodiments described herein may be implemented in the processors, such as the graphics processor 152 and/or the host processor 138, and in the accelerators dedicated to AI and/or NN processing such as AI accelerator 148 or other devices such as the FPGA 178.

The graphics processor 152, AI accelerator 148 and/or the host processor 138 may execute instructions 156 retrieved from the system memory 144 (e.g., a dynamic random-access memory) and/or the mass storage 176 to implement aspects as described herein. For example, a controller 164 of the AI accelerator 148 may execute an auxiliary training process on the second neural network 160. That is, the controller 164 identifies, with the first neural network 162 (e.g., a CNN), features of the input data 170 (e.g., a series of frames represented as a plurality of portions). The controller 164 then identifies, with a second neural network 160 (e.g., a TCN), that a predetermined amount of the first action is completed at a first portion of the input data 170. The controller 164 then generates a first loss based on the predetermined amount of the first action being identified as being completed at the first portion, and updates the second neural network 160 based on the first loss during the auxiliary training process. The second neural network 160 may be further trained to execute a primary task of segmenting raw input data to identify segments of actions, and label the segments accordingly. When the instructions 156 are executed, the computing system 158 may implement one or more aspects of the embodiments described herein. For example, the computing system 158 may implement one or more aspects of the embodiments described herein, for example, the auxiliary loss training architecture 100 (FIG. 1), method 300 (FIG. 2), ground truth generation architecture 350 (FIG. 3) and/or MFPL computing architecture 370 (FIG. 4) already discussed. The illustrated computing system 158 is therefore considered to be accuracy and efficiency-enhanced at least to the extent that the computing system 158 accurately segments and labels raw data with reduced compute and memory overhead.

FIG. 7 shows a semiconductor apparatus 186 (e.g., chip, die, package). The illustrated apparatus 186 includes one or more substrates 184 (e.g., silicon, sapphire, gallium arsenide) and logic 182 (e.g., transistor array and other integrated circuit/IC components) coupled to the substrate(s) 184. In an embodiment, the apparatus 186 is operated in an application development stage and the logic 182 performs one or more aspects of the embodiments described herein. For example, the apparatus 186 may generally implement the embodiments described herein, for example, the auxiliary loss training architecture 100 (FIG. 1), method 300 (FIG. 2), ground truth generation architecture 350 (FIG. 3) and/or MFPL computing architecture 370 (FIG. 4). The logic 182 may be implemented at least partly in configurable logic or fixed-functionality hardware logic. In one example, the logic 182 includes transistor channel regions that are positioned (e.g., embedded) within the substrate(s) 184. Thus, the interface between the logic 182 and the substrate(s) 184 may not be an abrupt junction. The logic 182 may also be considered to include an epitaxial layer that is grown on an initial wafer of the substrate(s) 184.

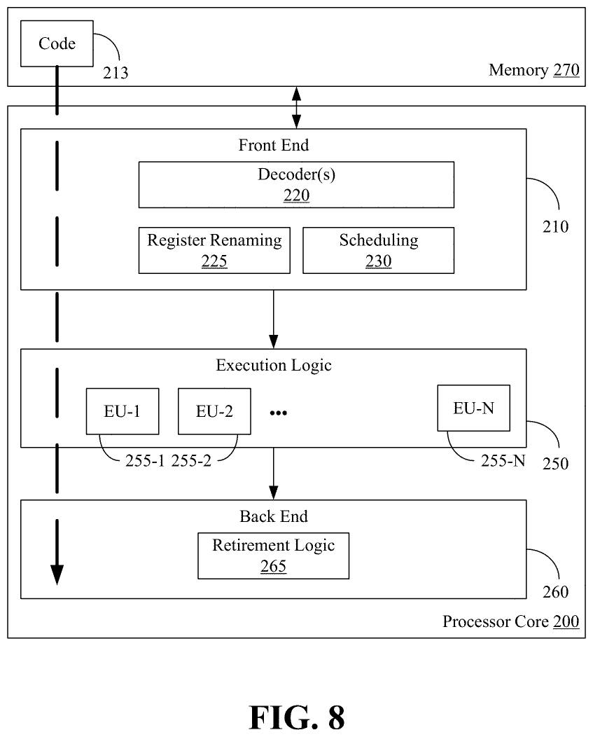

FIG. 8 illustrates a processor core 200 according to one embodiment. The processor core 200 may be the core for any type of processor, such as a micro-processor, an embedded processor, a digital signal processor (DSP), a network processor, or other device to execute code. Although only one processor core 200 is illustrated in FIG. 8, a processing element may alternatively include more than one of the processor core 200 illustrated in FIG. 8. The processor core 200 may be a single-threaded core or, for at least one embodiment, the processor core 200 may be multithreaded in that it may include more than one hardware thread context (or “logical processor”) per core.

FIG. 8 also illustrates a memory 270 coupled to the processor core 200. The memory 270 may be any of a wide variety of memories (including various layers of memory hierarchy) as are known or otherwise available to those of skill in the art. The memory 270 may include one or more code 213 instruction(s) to be executed by the processor core 200, wherein the code 213 may implement one or more aspects of the embodiments such as, for example, the auxiliary loss training architecture 100 (FIG. 1), method 300 (FIG. 2), ground truth generation architecture 350 (FIG. 3) and/or MFPL computing architecture 370 (FIG. 4) already discussed. The processor core 200 follows a program sequence of instructions indicated by the code 213. Each instruction may enter a front end portion 210 and be processed by one or more decoders 220. The decoder 220 may generate as its output a micro operation such as a fixed width micro operation in a predefined format, or may generate other instructions, microinstructions, or control signals which reflect the original code instruction. The illustrated front end portion 210 also includes register renaming logic 225 and scheduling logic 230, which generally allocate resources and queue the operation corresponding to the convert instruction for execution.

The processor core 200 is shown including execution logic 250 having a set of execution units 255-1 through 255-N. Some embodiments may include several execution units dedicated to specific functions or sets of functions. Other embodiments may include only one execution unit or one execution unit that can perform a particular function. The illustrated execution logic 250 performs the operations specified by code instructions.

After completion of execution of the operations specified by the code instructions, back-end logic 260 retires the instructions of the code 213. In one embodiment, the processor core 200 allows out of order execution but requires in order retirement of instructions. Retirement logic 265 may take a variety of forms as known to those of skill in the art (e.g., re-order buffers or the like). In this manner, the processor core 200 is transformed during execution of the code 213, at least in terms of the output generated by the decoder, the hardware registers and tables utilized by the register renaming logic 225, and any registers (not shown) modified by the execution logic 250.

Although not illustrated in FIG. 8, a processing element may include other elements on chip with the processor core 200. For example, a processing element may include memory control logic along with the processor core 200. The processing element may include I/O control logic and/or may include I/O control logic integrated with memory control logic. The processing element may also include one or more caches.

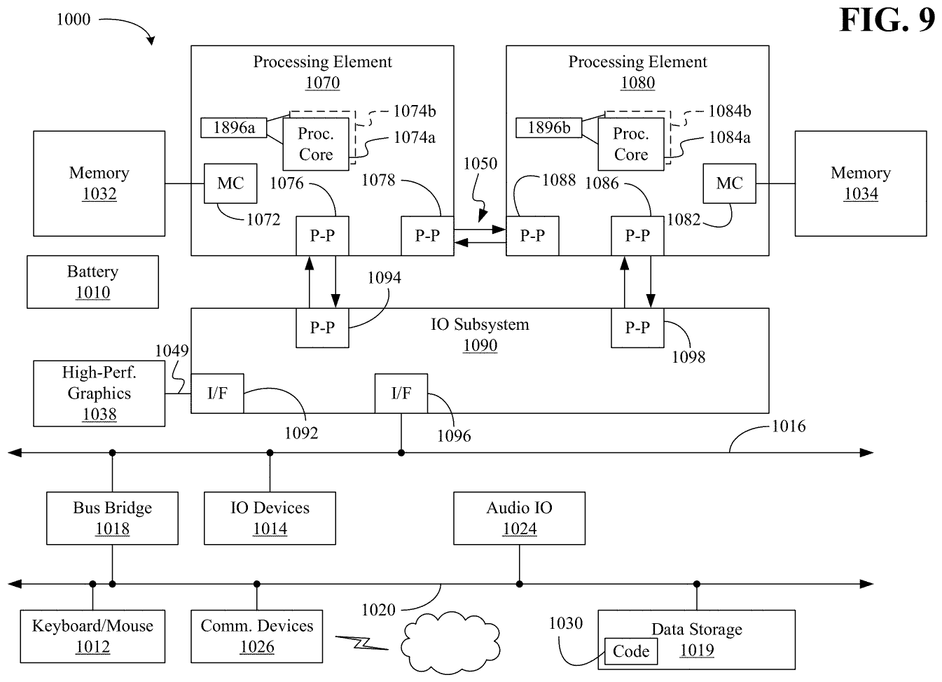

Referring now to FIG. 9, shown is a block diagram of a computing system 1000 embodiment in accordance with an embodiment. Shown in FIG. 9 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood any or all the interconnects illustrated in FIG. 9 may be implemented as a multi-drop bus rather than point-to-point interconnect.

As shown in FIG. 9, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner like that discussed above in connection with FIG. 8.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments is not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 9, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 9, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments is not so limited.

As shown in FIG. 9, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the one or more aspects of such as, for example, the auxiliary loss training architecture 100 (FIG. 1), method 300 (FIG. 2), ground truth generation architecture 350 (FIG. 3) and/or MFPL computing architecture 370 (FIG. 4) already discussed. Further, an audio I/O 1024 may be coupled to second bus 1020 and a battery 1010 may supply power to the computing system 1000.

Note that other embodiments are contemplated. For example, instead of the point-to-point architecture of FIG. 9, a system may implement a multi-drop bus or another such communication topology. Also, the elements of FIG. 9 may alternatively be partitioned using more or fewer integrated chips than shown in FIG. 9.

Additional Notes and Examples:

Example 1 includes a computing system comprising a data storage to store input data that includes a plurality of portions, wherein a subset of the plurality of portions collectively represents a first action, and a controller implemented in one or more of configurable logic or fixed-functionality logic, wherein the controller is to identify, with a neural network, that a predetermined amount of the first action is completed at a first portion of the plurality of portions, generate a first loss based on the predetermined amount of the first action being identified as being completed at the first portion, and update the neural network based on the first loss.

Example 2 includes the computing system of Example 1, wherein the controller is further to generate a first vector based on the subset of the plurality of portions and the predetermined amount of the first action being identified as being completed at the first portion, and identify a second vector that is a ground truth, wherein to generate the first loss, the controller is to compare the first vector to the second vector.

Example 3 includes the computing system of Example 2, wherein the controller is further to process, with the neural network, the subset of the plurality of portions to generate an output, wherein to generate the first vector, the controller is to execute, with a plurality of convolution layers, a plurality of convolutions on the output.

Example 4 includes the computing system of Example 3, wherein a plurality of residual connections connects the plurality of convolution layers.

Example 5 includes the computing system of any of Examples 1 to 4, wherein the controller is further to process, with the neural network, the plurality of portions to identify segments that correspond to a plurality of actions and label the segments with action labels, wherein the plurality of actions includes the first action, generate a second loss based on the segments and the action labels, and update the neural network based on the second loss.

Example 6 includes the computing system of any of Examples 1 to 5, wherein the controller is to identify, with a convolutional neural network, features of the plurality of portions, the input data is one or more of video data or audio data, the neural network is a temporal convolutional network, and to identify that the predetermined amount of the first action is completed at the first portion, the controller is to process the features with the temporal convolutional network, wherein the predetermined amount corresponds to a midpoint of the first action.

Example 7 includes a semiconductor apparatus, the semiconductor apparatus comprising one or more substrates, and logic coupled to the one or more substrates, wherein the logic is implemented in one or more of configurable logic or fixed-functionality logic, the logic coupled to the one or more substrates to identify, with a neural network, that a predetermined amount of a first action is completed at a first portion of a plurality of portions, wherein a subset of the plurality of portions collectively represents the first action, generate a first loss based on the predetermined amount of the first action being identified as being completed at the first portion, and update the neural network based on the first loss.

Example 8 includes the apparatus of Example 7, wherein the logic coupled to the one or more substrates is further to generate a first vector based on the subset of the plurality of portions and the predetermined amount of the first action being identified as being completed at the first portion, and identify a second vector that is a ground truth, wherein to generate the first loss, the logic coupled to the one or more substrates is to compare the first vector to the second vector.

Example 9 includes the apparatus of Example 8, wherein the logic coupled to the one or more substrates is further to process, with the neural network, the subset of the plurality of portions to generate an output, wherein to generate the first vector, the logic coupled to the one or more substrates is to execute, with a plurality of convolution layers, a plurality of convolutions on the output.

Example 10 includes the apparatus of Example 9, wherein a plurality of residual connections connects the plurality of convolution layers.

Example 11 includes the apparatus of any of Examples 7 to 10, wherein the logic coupled to the one or more substrates is further to process, with the neural network, the plurality of portions to identify segments that correspond to a plurality of actions and label the segments with action labels, wherein the plurality of actions includes the first action, generate a second loss based on the segments and the action labels, and update the neural network based on the second loss.

Example 12 includes the apparatus of any of Example 7 to 11, wherein the logic coupled to the one or more substrates is to identify, with a convolutional neural network, features of the plurality of portions, the plurality of portions is one or more of video data or audio data, the neural network is a temporal convolutional network, and to identify that the predetermined amount of the first action is completed at the first portion, the logic coupled to the one or more substrates is to process the features with the temporal convolutional network, wherein the predetermined amount corresponds to a midpoint of the first action.

Example 13 includes the apparatus of any of Examples 7 to 12, wherein the logic coupled to the one or more substrates includes transistor channel regions that are positioned within the one or more substrates.

Example 14 includes at least one computer readable storage medium comprising a set of executable program instructions, which when executed by a computing system, cause the computing system to identify, with a neural network, that a predetermined amount of a first action is completed at a first portion of a plurality of portions, wherein a subset of the plurality of portions collectively represents the first action, generate a first loss based on the predetermined amount of the first action being identified as being completed at the first portion, and update the neural network based on the first loss.

Example 15 includes the at least one computer readable storage medium of Example 14, wherein the instructions, when executed, further cause the computing system to generate a first vector based on the subset of the plurality of portions and the predetermined amount of the first action being identified as being completed at the first portion, and identify a second vector that is a ground truth, wherein to generate the first loss, the instructions, when executed, further cause the computing system to compare the first vector to the second vector.

Example 16 includes the at least one computer readable storage medium of Example 15, wherein the instructions, when executed, further cause the computing system to process, with the neural network, the subset of the plurality of portions to generate an output, wherein to generate the first vector, the instructions, when executed, further cause the computing system to execute, with a plurality of convolution layers, a plurality of convolutions on the output.

Example 17 includes the at least one computer readable storage medium of Example 16, wherein a plurality of residual connections connects the plurality of convolution layers.

Example 18 includes the at least one computer readable storage medium of any of Examples 14 to 17, wherein the instructions, when executed, further cause the computing system to process, with the neural network, the plurality of portions to identify segments that correspond to a plurality of actions and label the segments with action labels, wherein the plurality of actions includes the first action, generate a second loss based on the segments and the action labels, and update the neural network based on the second loss.

Example 19 includes the at least one computer readable storage medium of any of Examples 14 to 18, wherein the instructions, when executed, further cause the computing system to identify, with a convolutional neural network, features of the plurality of portions, the plurality of portions is one or more of video data or audio data, the neural network is a temporal convolutional network, and to identify that the predetermined amount of the first action is completed at the first portion, the instructions, when executed, further cause the computing system to process the features with the temporal convolutional network, wherein the predetermined amount corresponds to a midpoint of the first action.

Example 20 includes a method comprising identifying, with a neural network, that a predetermined amount of a first action is completed at a first portion of a plurality of portions, wherein a subset of the plurality of portions collectively represents the first action, generating a first loss based on the predetermined amount of the first action being identified as being completed at the first portion, and updating the neural network based on the first loss.

Example 21 includes the method of Example 20, further comprising generating a first vector based on the subset of the plurality of portions and the predetermined amount of the first action being identified as being completed at the first portion, and identifying a second vector that is a ground truth, wherein the generating the first loss, comprises comparing the first vector to the second vector.

Example 22 includes the method of Example 21, further comprising processing, with the neural network, the subset of the plurality of portions to generate an output, wherein the generating the first vector includes executing, with a plurality of convolution layers, a plurality of convolutions on the output.

Example 23 includes the method of Example 22, wherein a plurality of residual connections connects the plurality of convolution layers.

Example 24 includes the method of any of Examples 20 to 23, wherein the method further comprises processing, with the neural network, the plurality of portions to identify segments that correspond to a plurality of actions and label the segments with action labels, wherein the plurality of actions includes the first action, generating a second loss based on the segments and the action labels, and updating the neural network based on the second loss.

Example 25 includes the method of any of Examples 20 to 24, wherein the method further comprises identifying, with a convolutional neural network, features of the plurality of portions, the plurality of portions is one or more of video data or audio data, the neural network is a temporal convolutional network, and the identifying that the predetermined amount of the first action is completed at the first portion, comprises processing the features with the temporal convolutional network, wherein the predetermined amount corresponds to a midpoint of the first action.

Example 26 includes a semiconductor apparatus, the semiconductor apparatus comprising means for identifying, with a neural network, that a predetermined amount of a first action is completed at a first portion of a plurality of portions, wherein a subset of the plurality of portions collectively represents the first action, means for generating a first loss based on the predetermined amount of the first action being identified as being completed at the first portion, and means for updating the neural network based on the first loss.

Example 27 includes the apparatus of Example 26, further comprising means for generating a first vector based on the subset of the plurality of portions and the predetermined amount of the first action being identified as being completed at the first portion, and means for identifying a second vector that is a ground truth, wherein the means for generating the first loss, comprises means for comparing the first vector to the second vector.

Example 28 includes the apparatus of Example 27, further comprising means for processing, with the neural network, the subset of the plurality of portions to generate an output, wherein the means for generating the first vector includes executing, with a plurality of convolution layers, a plurality of convolutions on the output.

Example 29 includes the apparatus of Example 28, wherein a plurality of residual connections connects the plurality of convolution layers.

Example 30 includes the apparatus of any of Examples 26 to 29, wherein the apparatus further comprises means for processing, with the neural network, the plurality of portions to identify segments that correspond to a plurality of actions and label the segments with action labels, wherein the plurality of actions includes the first action, means for generating a second loss based on the segments and the action labels, and means for updating the neural network based on the second loss.

Example 31 includes the apparatus of any of Examples 26 to 30, wherein the apparatus further comprises means for identifying, with a convolutional neural network, features of the plurality of portions, the plurality of portions is one or more of video data or audio data, the neural network is a temporal convolutional network, and the means for identifying that the predetermined amount of the first action is completed at the first portion, comprises means for processing the features with the temporal convolutional network, wherein the predetermined amount corresponds to a midpoint of the first action.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical, or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of” “A, B or C” may mean A, B, C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a data storage to store input data that includes a plurality of portions, wherein a subset of the plurality of portions collectively represents a first action; and
a controller implemented in one or more of configurable logic or fixed-functionality logic, wherein the controller is to:
identify, with a neural network, that a predetermined amount of the first action is completed at a first portion of the plurality of portions,
generate a first loss based on the predetermined amount of the first action being identified as being completed at the first portion, and
update the neural network based on the first loss.

2. The computing system of claim 1, wherein the controller is further to:
generate a first vector based on the subset of the plurality of portions and the predetermined amount of the first action being identified as being completed at the first portion, and
identify a second vector that is a ground truth,
wherein to generate the first loss, the controller is to compare the first vector to the second vector.

3. The computing system of claim 2, wherein the controller is further to:
process, with the neural network, the subset of the plurality of portions to generate an output,
wherein to generate the first vector, the controller is to execute, with a plurality of convolution layers, a plurality of convolutions on the output.

4. The computing system of claim 3, wherein a plurality of residual connections connects the plurality of convolution layers.

5. The computing system of claim 1, wherein the controller is further to:
process, with the neural network, the plurality of portions to identify segments that correspond to a plurality of actions and label the segments with action labels, wherein the plurality of actions includes the first action,
generate a second loss based on the segments and the action labels, and
update the neural network based on the second loss.

6. The computing system of claim 1, wherein:
the controller is to identify, with a convolutional neural network, features of the plurality of portions;
the input data is one or more of video data or audio data;
the neural network is a temporal convolutional network; and
to identify that the predetermined amount of the first action is completed at the first portion, the controller is to process the features with the temporal convolutional network, wherein the predetermined amount corresponds to a midpoint of the first action.

7. A semiconductor apparatus, the semiconductor apparatus comprising:
one or more substrates; and
logic coupled to the one or more substrates, wherein the logic is implemented in one or more of configurable logic or fixed-functionality logic, the logic coupled to the one or more substrates to:
identify, with a neural network, that a predetermined amount of a first action is completed at a first portion of a plurality of portions, wherein a subset of the plurality of portions collectively represents the first action;
generate a first loss based on the predetermined amount of the first action being identified as being completed at the first portion; and
update the neural network based on the first loss.

8. The apparatus of claim 7, wherein the logic coupled to the one or more substrates is further to:
generate a first vector based on the subset of the plurality of portions and the predetermined amount of the first action being identified as being completed at the first portion, and
identify a second vector that is a ground truth,
wherein to generate the first loss, the logic coupled to the one or more substrates is to compare the first vector to the second vector.

9. The apparatus of claim 8, wherein the logic coupled to the one or more substrates is further to:
process, with the neural network, the subset of the plurality of portions to generate an output,
wherein to generate the first vector, the logic coupled to the one or more substrates is to execute, with a plurality of convolution layers, a plurality of convolutions on the output.

10. The apparatus of claim 9, wherein a plurality of residual connections connects the plurality of convolution layers.

11. The apparatus of claim 7, wherein the logic coupled to the one or more substrates is further to:
process, with the neural network, the plurality of portions to identify segments that correspond to a plurality of actions and label the segments with action labels, wherein the plurality of actions includes the first action,
generate a second loss based on the segments and the action labels, and
update the neural network based on the second loss.

12. The apparatus of claim 7, wherein:
the logic coupled to the one or more substrates is to identify, with a convolutional neural network, features of the plurality of portions;
the plurality of portions is one or more of video data or audio data;
the neural network is a temporal convolutional network; and
to identify that the predetermined amount of the first action is completed at the first portion, the logic coupled to the one or more substrates is to process the features with the temporal convolutional network, wherein the predetermined amount corresponds to a midpoint of the first action.

13. The apparatus of claim 7, wherein the logic coupled to the one or more substrates includes transistor channel regions that are positioned within the one or more substrates.

14. At least one computer readable storage medium comprising a set of executable program instructions, which when executed by a computing system, cause the computing system to:
identify, with a neural network, that a predetermined amount of a first action is completed at a first portion of a plurality of portions, wherein a subset of the plurality of portions collectively represents the first action;
generate a first loss based on the predetermined amount of the first action being identified as being completed at the first portion; and
update the neural network based on the first loss.

15. The at least one computer readable storage medium of claim 14, wherein the instructions, when executed, further cause the computing system to:
generate a first vector based on the subset of the plurality of portions and the predetermined amount of the first action being identified as being completed at the first portion, and
identify a second vector that is a ground truth,
wherein to generate the first loss, the instructions, when executed, further cause the computing system to compare the first vector to the second vector.

16. The at least one computer readable storage medium of claim 15, wherein the instructions, when executed, further cause the computing system to:
process, with the neural network, the subset of the plurality of portions to generate an output,
wherein to generate the first vector, the instructions, when executed, further cause the computing system to execute, with a plurality of convolution layers, a plurality of convolutions on the output.

17. The at least one computer readable storage medium of claim 16, wherein a plurality of residual connections connects the plurality of convolution layers.

18. The at least one computer readable storage medium of claim 14, wherein the instructions, when executed, further cause the computing system to:
process, with the neural network, the plurality of portions to identify segments that correspond to a plurality of actions and label the segments with action labels, wherein the plurality of actions includes the first action,
generate a second loss based on the segments and the action labels, and
update the neural network based on the second loss.

19. The at least one computer readable storage medium of claim 14, wherein:
the instructions, when executed, further cause the computing system to identify, with a convolutional neural network, features of the plurality of portions;
the plurality of portions is one or more of video data or audio data;
the neural network is a temporal convolutional network; and
to identify that the predetermined amount of the first action is completed at the first portion, the instructions, when executed, further cause the computing system to process the features with the temporal convolutional network, wherein the predetermined amount corresponds to a midpoint of the first action.

20. A method comprising:
identifying, with a neural network, that a predetermined amount of a first action is completed at a first portion of a plurality of portions, wherein a subset of the plurality of portions collectively represents the first action;
generating a first loss based on the predetermined amount of the first action being identified as being completed at the first portion; and
updating the neural network based on the first loss.

21. The method of claim 20, further comprising:
generating a first vector based on the subset of the plurality of portions and the predetermined amount of the first action being identified as being completed at the first portion, and
identifying a second vector that is a ground truth,
wherein the generating the first loss, comprises comparing the first vector to the second vector.

22. The method of claim 21, further comprising:
processing, with the neural network, the subset of the plurality of portions to generate an output,
wherein the generating the first vector includes executing, with a plurality of convolution layers, a plurality of convolutions on the output.

23. The method of claim 22, wherein a plurality of residual connections connects the plurality of convolution layers.

24. The method of claim 20, wherein the method further comprises:
processing, with the neural network, the plurality of portions to identify segments that correspond to a plurality of actions and label the segments with action labels, wherein the plurality of actions includes the first action,
generating a second loss based on the segments and the action labels, and
updating the neural network based on the second loss.

25. The method of claim 20, wherein:
the method further comprises identifying, with a convolutional neural network, features of the plurality of portions;
the plurality of portions is one or more of video data or audio data;
the neural network is a temporal convolutional network; and
the identifying that the predetermined amount of the first action is completed at the first portion, comprises processing the features with the temporal convolutional network, wherein the predetermined amount corresponds to a midpoint of the first action.
